(19) United States
(12) Patent Application Publication
(10) Pub. No.: US 2023/0022345 A1
(43) Pub. Date: Jan. 26, 2023

(54) UNIFIED POD AND MATERIAL CONVEYING SYSTEM

(71) Applicant: CHANGXIN MEMORY TECHNOLOGIES, INC., Hefei City, Anhui (CN)

(72) Inventors: Mingxing CHENG, Hefei City, Anhui (CN); Guangjie ZHANG, Hefei City, Anhui (CN)

(21) Appl. No.: 17/439,084

(22) PCT Filed: Jun. 7, 2021
(86) PCT No.: PCT/CN2021/098726

§ 371 Date: Sep. 14, 2021

(30) Foreign Application Priority Data
Sep. 30, 2020 (CN) 202011066333.6

(51) Int. Cl. H01L 21/673; B65D 25/10; B65D 25/22; B65D 81/05; B65D 81/20; B65D 85/30; B65G 17/20; B65G 17/32; B65G 17/40; H01L 21/677; H01L 21/68

(52) U.S. Cl. CPC H01L 21/67393; B65D 25/10; B65D 25/22; B65D 81/05; B65D 81/20; B65D 85/30; B65G 17/20; B65G 17/32; B65G 17/40; H01L 21/677; H01L 21/68

(57) ABSTRACT

The present application provides a unified pod and a material conveying system. The unified pod includes an accommodating box and a gas storage box, wherein gas inlets and gas outlets are formed on the accommodating box, the gas inlets of the accommodating box are connected with the gas storage box; a first sensor for detecting a pressure value in the accommodating box is further arranged in the accommodating box.

### CROSS-REFERENCE TO RELATED APPLICATIONS

The present application claims the priority to Chinese Patent Application 202011066333.6, titled “UNIFIED POD AND MATERIAL CONVEYING SYSTEM”, filed to China National Intellectual Property Administration on Sep. 30, 2020, which is incorporated herein by reference in its entirety.

### TECHNICAL FIELD

The present application relates to the material conveying technical field, and in particular to a unified pod and a material conveying system.

### BACKGROUND

The semiconductor manufacturing process usually includes multiple processes, for example, lithography, deposition, curing, annealing, etc. Wafers are usually placed in different devices for corresponding processes. Wafers can be stored in unified pods, in order to be conveyed to different devices. For example, the unified pods are front opening unified pods (FOUP).

The micro-environment in the unified pod has an important impact on the surface morphology of the wafer. In order to prevent the residues in the unified pod at the end of a process or the contaminants in the external environment from entering the unified pod to damage the surface of the wafer, the unified pod is generally of a closed structure, and an inert gas (e.g., nitrogen) is filled in the unified pod to remove the residues or contaminants in the unified pod, thereby reducing and avoiding surface defects of the wafer.

However, when the waiting time between processes is long, the inert gas in the unified pod is easy to leak, thus increasing the surface defects of wafers and reducing the yield of wafers.

### SUMMARY

The present application provides a unified pod and a material conveying system.

In a first aspect, the present application provides a unified pod, comprising an accommodating box and a gas storage box, wherein gas inlets and gas outlets are formed on the accommodating box; the gas inlets of the accommodating box are connected with the gas storage box; a first sensor is further arranged in the accommodating box; the first sensor detects a pressure value in the accommodating box; in initial state, the gas outlets of the accommodating box are opened, and the gas storage box fills the accommodating box with a protective gas though the gas inlets of the accommodating box; and, when the time from the initial state is greater than a first set time and the pressure value is less than a first set value, the gas outlets of the accommodating box are closed, and the gas storage box fills the accommodating box with the protective gas by the gas inlets of the accommodating box.

The unified pod according to the present application has the following advantages.

In the present application, the unified pod comprises an accommodating box and a gas storage box. An object to be conveyed is placed in the accommodating box, and a protective gas is filled in the gas storage box. Gas inlets and gas outlets are formed on the accommodating box, and the gas inlets of the accommodating box are connected with the gas storage box. A first sensor for detecting a pressure value in the accommodating box is further arranged in the accommodating box. In initial state, the gas outlets of the accommodating box are opened, and the gas storage box fills the accommodating box with the protective gas by the gas inlets of the accommodating box. When the time from the initial state is greater than a first set time and the pressure value is less than a first set value, the gas outlets of the accommodating box are closed, and the gas storage box fills the accommodating box with the protective gas by the gas inlets of the accommodating box. The accommodating box is continuously filled with the protective gas after a waste gas is discharged, so an object to be conveyed in the accommodating box can be prevented from being polluted, the surface defects of the object to be conveyed are reduced, and the yield of the object to be conveyed is improved.

In a second aspect, the present application further provides a material conveying system, comprising a conveyor chain, a driving device and the unified pod described above; and, the unified pod is suspended on the conveyor chain, and the driving device drives the conveyor chain to move.

The material conveying system according to the present application comprises the unified pod described above and therefore has the advantages of the unified pod, so that the surface detects of an object to be conveyed can be reduced and the yield of the object to be conveyed can be improved. The specific effects are described above and will not be repeated here.

### BRIEF DESCRIPTION OF THE DRAWINGS

FIG. 1 is a schematic structure diagram of a unified pod according to an embodiment of the present application;

FIG. 2 is a schematic structure diagram of a gas storage box according to an embodiment of the present application;

FIG. 3 is a mounting diagram of the gas storage box according to an embodiment of the present application; and

FIG. 4 is a flowchart of the operation of the unified pod according to an embodiment of the present application.

### DETAILED DESCRIPTION

In the embodiments of the present application, the unified pod comprises an accommodating box and a gas storage box, and a first sensor for detecting a pressure value in the accommodating box is arranged in the accommodating box. After a waste gas is discharged through the accommodating box and when the pressure value is less than a first set value, gas outlets of the accommodating box are closed, and the gas storage box fills the accommodating box with a protective gas by gas inlets of the accommodating box, so that the accommodating box is continuously filled with the protective gas, thereby preventing an object to be conveyed in the accommodating box from being polluted and improving the yield of the object to be conveyed.

In order to make the objectives, features and advantages of the embodiments of the present application more obvious and understandable, the technical solutions in the embodiments of the present application will be described below clearly and completely with reference to the drawings in the embodiments of the present application. Apparently, the embodiments to be described are only some but not all of the embodiments of the present application. Based on the embodiments of the present application, all other embodiments obtained by a person of ordinary skill in the art without paying any creative effort shall fall into the protection scope of the present application.

The material conveying system according to the embodiments of the present application is applied to the manufacturing process of various different products, for example, semiconductor products, precision electronic products, instruments, meters, mold products, etc. The object to be conveyed can be transferred, stored, machined or surface treated between different devices by the material conveying system.

For example, by taking semiconductor manufacturing as an example, wafers usually undergo processes such as deposition, grinding, lithography, doping and cleaning to form desired semiconductor products. Different processes often need to be performed on different devices. For example, thin films are formed on wafers by a deposition device; wafers are planarized by a grinding device; wafers are patterned by a lithographic device; and, ion implantation is performed in particular regions of wafers by an implantation device. Wafers can be moved and stored between the devices by a material conveying system so as to realize corresponding processes.

The embodiments of the present application and the following embodiments are described in detail by taking a material conveying system for transporting wafers as an example.

The material conveying system according to the embodiments of the present application comprises a conveying device, a driving device and a unified pod, wherein a wafer is placed in the unified pod, and the conveying device drives the unified pod to move. Exemplarily, the conveying device is a conveyor belt or a conveyor chain, and the conveying device is usually detachably connected to the unified pod. The driving device is connected to the conveying device to drive the conveying device to move, so that the unified pod and the wafer placed in the unified pod are transferred to different processes.

Further, in addition to the above devices, the material conveying system according to the embodiments of the present application further comprise a control system configured to control the driving device, the unified pod, etc. The control system may comprise a manufacturing execution system (MES). The MES is in signal connection to the unified pod to receive signals from the unified pod or transmit signals to the unified pod and control the opening or closing of a valve in the unified pod.

When in use of the material conveying system, a wafer is placed in the unified pod after a corresponding process is completed in one device. The unified pod may be suspended on the conveyor chain, and the driving device drives the conveyor chain to move to a next device, so that the unified pod is moved to the next device, and the wafer is taken out from the unified pod for other processes.

The unified pod may be mounted on the conveying device by a clamping part. For example, the unified pod is suspended on the conveyor chain by a manipulator. The unified pod may also be mounted on the conveying device by an automated transportation device. For example, the unified pod is docked with the conveyor chain by an overhead hoist transport (OHT) or an automated guided vehicle (AGV), so that the unified pod is transferred and mounted on the conveyor chain.

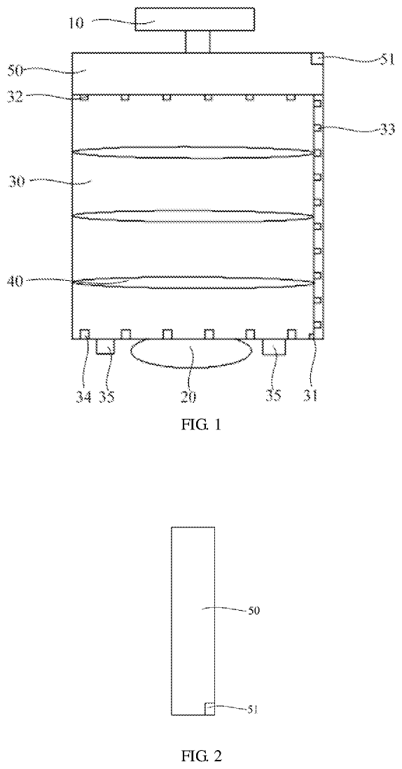

Referring to FIG. 1, in some embodiments, a connecting portion 10 is generally arranged on the top of the unified pod, and the unified pod is suspended on the conveyor chain of the material conveying system by the connecting portion 10 so as to allow the material conveying system to move the unified pod. The connecting portion 10 may be a flange, a handle, etc. Exemplarily, the connecting portion 10 may be located in the middle of the top of the unified pod, thereby preventing wafers 40 from moving in the unified pod and being damaged due to the inclination of the unified pod in the process of conveying the wafers 40.

A mounting seat 20 is generally arranged on the bottom of the unified pod. The mounting seat 20 is configured to support the unified pod when the unified pod is stopped, and connect the unified pod to another device to ensure the unified pod to be unmoved when the wafer undergoes the related processes.

Continuously referring to FIG. 1, the unified pod comprises an accommodating box and a gas storage box 50. The accommodating box 30 is configured to accommodate wafers 40, and the gas storage box 50 is configured to store a protective gas. The protective gas may be an inert gas. For example, the protective gas is one or more of argon, helium or nitrogen.

A plurality of wafer storage shelves arranged at intervals may be arranged in the accommodating box 30 to accommodate wafers 40, so that a plurality of wafers 40 are stacked and separated from each other. Exemplarily, the wafer storage shelves are arranged on an inner sidewall of the accommodating box 30, and the wafer storage shelves may be grooves formed on the inner sidewall of the accommodating box 30. One wafer 40 is placed on each wafer storage shelf, and the wafer 40 is horizontally placed in the accommodating box 30 as shown in FIG. 1.

The accommodating box 30 may be columnar. For example, the accommodating box 30 may be cylindrical, elliptically cylindrical or prismatic. When the accommodating box 30 is cylindrical, the wafers 40 have a circular shape matched with the accommodating box 30. In such a design, the utilization of space in the accommodating box 30 is higher. In the embodiments of the present application and the following embodiments, the description is given by taking the accommodating box 30 being cylindrical as an example. However, it should be understood that the accommodating box 30 is not limited to a cylindrical shape.

Continuously referring to FIG. 1, gas inlets, gas outlets 35 and a first sensor 31 are arranged in the accommodating box 30. The gas inlets of the accommodating box 30 are connected with the gas storage box 50, and the gas outlets of the accommodating box 30 are connected with the outside. The protective gas is filled into the accommodating box 30 by the gas inlets of the accommodating box 30, and the gas is discharged by the gas outlets 35 of the accommodating box 30, so that the waste gas can be discharged through the accommodating box 30 and the cleanness in the accommodating box 30 can be maintained. That is, the protective gas can be maintained within the accommodating box 30 to cover wafers 40, thereby preventing contaminants from contacting the wafers 40 and damaging the surfaces of the wafers 40.

The gas inlets of the accommodating box 30 may be formed on the top, side or bottom of the accommodating box 30, and the gas outlets 35 of the accommodating box 30 may also be formed on the top, side or bottom of the accommodating box 30. There may be a plurality of gas inlets and a plurality of gas outlets 35 of the accommodating box 30 in order to improve the efficiency of discharging the waste gas from and filling the protective gas into the accommodating box 30. Referring to FIG. 1, a plurality of first gas inlets 32 are formed on a sidewall of the accommodating box 30, and the plurality of first gas inlets 32 are arranged at intervals.

Exemplarily, the plurality of first gas inlets 32 may be arranged at intervals along an axial direction of the accommodating box 30, that is, a dashed line formed by successively connecting the plurality of first gas inlets 32 is parallel to the axis (center line) of the accommodating box 30. As shown in FIG. 1 the plurality of first gas inlets 32 are arranged in a vertical direction, that is, each first gas inlet 32 is located directly above or below an adjacent first gas inlet 32. In order to achieve a better gas intake effect in the accommodating box 30, the plurality of first gas inlets 32 may be arranged at equal intervals.

It should be understood that there is a gas flow passage between the accommodating box 30 and the gas storage box 50. As shown in FIG. 1, the vertical portion on the right of the accommodating box 30 is a gas flow passage, and the gas flow passage connects the gas storage box with the plurality of first gas inlets 32.

It is to be noted that the plurality of first gas inlets 32 may also be circumferentially arranged along the sidewall of the accommodating box 30. For example, the plurality of first gas inlets 32 are spirally arranged along the sidewall of the accommodating box 30, and the spiral center line of the plurality of first gas inlets 32 is overlapped with the center line of the accommodating box 30.

A plurality of second gas inlets 33 may be formed on the top of the accommodating box 30, and a plurality of third gas inlets 34 may be formed on the bottom of the accommodating box 30, so that the gas intake rate of the accommodating box 30 is further improved, and the accommodating box 30 can be filled with the protective gas quickly. There are also a plurality of gas outlets 35 of the accommodating box 30, and the plurality of gas outlets 35 are arranged on the bottom of the accommodating box 30, so that the waste gas in the accommodating box 30 can be discharged quickly.

The first gas inlets 32, the second gas inlets 33 and the third gas inlets 34 may together form the gas inlets of the accommodating box 30. The number of the first gas inlets 32 may be greater than the number of the second gas inlets 33 and the number of the third gas inlets 34, and the number of the second gas inlets 33 may be the same as the number of the third gas inlets 34. For example, each second gas inlet 33 is arranged opposite to the third gas inlet 34.

Continuously referring to FIG. 1, a first sensor 31 is further arranged in the accommodating box 30, and the first sensor 31 detects a pressure value in the accommodating box 30. The first sensor 31 may be a pressure sensor which detects and transmits the pressure information in the accommodating box 30. For example, the first sensor 31 may transmit the detected pressure information to a processor of the unified pod in a wireless transmission manner.

The processor of the unified pod may be arranged separately. For example, the processor is arranged in the unified pod. The processor may also be a control system in the material conveying system or a part of the control system. The processor is in signal connection to the first sensor 31, and can receive the pressure information detected by the first sensor 31 and compare the pressure information with a first preset value, wherein the first preset value may be an external atmospheric pressure value. The processor can also control the valve actions of the air inlets and gas outlets 35 of the accommodating box 30, so as to realize the opening or closing of the air inlets and gas outlets 35 of the accommodating box 30.

It is to be noted that, one first sensor 31 may be arranged in the accommodating box 30, for example, the first sensor 31 being arranged on the bottom of the accommodating box 30; and, a plurality of first sensors 31 may also be arranged in the accommodating box 30, and the plurality of first sensors 31 are arranged at different positions in the accommodating box 30 to improve the detection accuracy of the pressure value in the accommodating box 30.

Referring to FIG. 4, the operation process of the unified pod according to an embodiment of the present application will be described below in detail. In the unified pod, the accommodating box 30 comprises a plurality of first gas inlets 32 formed on the sidewall of the accommodating box 30, a plurality of second gas inlets 33 formed on the top of the accommodating box 30, and a plurality of third gas inlets 34 and a plurality of gas outlets 35 formed on the bottom of the accommodating box 30. That is, the plurality of third gas inlets 34 of the accommodating box 30 are located on the same side of the accommodating box 30 as the plurality of gas outlets 35 of the accommodating box 30. As shown in FIG. 1, the plurality of gas outlets 35 may be arranged around the mounting seat 20 of the unified pod.

In initial state, the gas inlets and gas outlets 35 of the accommodating box 30 are opened, and the accommodating box 30 performs a waste gas discharge process. The gas storage box 50 fills the accommodating box 30 with a protective gas by the gas inlets of the accommodating box 30, so that the waste gas is discharged through the gas outlets 35 of the accommodating box 30.

In some possible examples, the first gas inlets 32, the second gas inlets 33 and the gas outlets 35 of the accommodating box 30 are opened, and the gas storage box 50 fills the accommodating box 30 with the protective gas at a second flow rate by the first gas inlets 32 and second gas inlets 33 of the accommodating box 30 to discharge the waste gas from the gas outlets 35 of the accommodating box 30, and the third gas inlets 34 of the accommodating box 30 are closed to prevent the gas at the third gas inlets 34 of the accommodating box 30 from back flushing the waste gas and causing the waste gas not to be discharged completely.

It should be understood that the flow rate at which the protective gas in the gas storage box 50 flows by the first gas inlets 32 of the accommodating box 30 may be the same as the flow rate at which the protective gas flows by the second gas inlets 33 of the accommodating box 30, that is, the both are the second flow rate. With such an arrangement, the gas intake of each gas inlet of the accommodating box 30 is balanced.

In other possible examples, the second gas inlets 33 and the gas outlets 35 of the accommodating box 30 are opened, the first gas inlets 32 and the third gas inlets 34 are closed, and the gas storage box 50 fills the accommodating box 30 at the second flow rate by the second gas inlets 33, so that the waste gas is discharged through the gas outlets 35 of the accommodating box 30.

It is to be noted that the initial state can be controlled by the processor of the unified pod. That is, when the first sensor 31 in the accommodating box 30 receives a cleaning instruction from the processor of the unified pod, the unified pod is in the initial state, and the accommodating box 30 discharges the waste gas. That is, the state where the accommodating box 30 starts to discharge the waste gas is the initial state.

When the time from the initial state is less than a first set time, the accommodating box 30 always discharges the waste gas. In other words, when the time from the initial state is less than the first set time, the gas inlets and gas outlets 35 of the accommodating box 30 are opened, and the gas storage box 50 fills the accommodating box 30 with the protective gas by the gas inlets of the accommodating box 30, so that the waste gas in the accommodating box 30 is discharged through the gas outlets 35 of the accommodating box 30.

The first preset time is greater than or equal to the time required for the accommodating box 30 to discharge the waste gas, and is set according to the volume, gas intake flow and gas discharge flow of the accommodating box 30. Exemplarily, the first preset time may be 5 to 10 min. It should be understood that, when the time from the initial time is equal to the first preset time, the waste gas in the accommodating box 30 has been discharged and the accommodating box 30 is filled with the protective gas. At this time, the gas inlets and gas outlets 35 of the accommodating box 30 can be closed.

The time from the initial stage may be detected by a timing device, and the timing device is in signal connection to the processor of the unified pod. The timing device may be separately arranged in the accommodating box 30 and in signal connection to the processor. The timing device may also be arranged outside the accommodating box 30 and in signal connection to the processor. For example, the timing device is a part of the processor.

The timing device may be a timing counter or a timer. Exemplarily, the timing device is a timing counter. When the unified pod is in the initial state, the timing counter starts to time. When the timing of the timing counter reaches the first preset time, the processor controls the gas inlets and gas outlets of the unified pod to close. Alternatively, the timing device is a timer, and the time of the timer is equal to the first preset time. When the unified pod is in the initial state, the timer starts to count down. After the timer has counted down, the processor controls the gas inlets and gas outlets of the unified pod to close.

When the time from the initial state is greater than the first set time, the unified pod executes the following process.

When the pressure value detected by the first sensor 31 is less than a first set value, the gas outlets 35 of the accommodating box 30 are closed, and the gas inlets of the accommodating box 30 are opened. The gas storage box 50 fills the accommodating box 30 with the protective gas by the gas inlets of the accommodating box 30, so that the accommodating box 30 is filled with the protective gas, and the wafer 40 in the accommodating box 30 is always kept in the protective gas.

Exemplarily, when the pressure value detected by the first sensor 31 is less than the first set value, the first gas inlets 32, the second gas inlets 33 and the third gas inlets 34 of the accommodating box 30 are opened, and the gas storage box 50 fills the accommodating box 30 with the protective gas at a first flow rate. That is, the protective gas is filled into the accommodating box 30 by the first gas inlets 32, the second gas inlets 33 and the third gas inlets 34 at the first flow rate. The first flow rate may be less than the second flow rate.

When the pressure value detected by the first sensor 31 is equal to the first set value, the gas inlets and gas outlets 35 of the accommodating box 30 are closed. When the pressure value in the accommodating box 30 is equal to the external atmospheric pressure value, the accommodating box 30 is in a balanced state. At this time, the accommodating box 30 neither takes in gas nor discharges gas.

When the pressure value detected by the first sensor 31 is greater than the first set value, the gas inlets of the accommodating box 30 are closed, the gas outlets of the accommodating box 30 are opened, and the accommodating box 30 discharges the protective gas to the outside to reduce the pressure value in the accommodating box 30, so as to prevent the accommodating box 30 from being damaged due to a too high internal pressure.

It should be understood that it is not sequential that the pressure value detected by the first sensor 31 is less than the first set value, the pressure value detected by the first sensor 31 is equal to the first set value and the pressure value detected by the first sensor 31 is greater than or equal to the first set value. The processor of the unified pod controls the valve actions of the gas inlets and gas outlets 35 of the accommodating box 30 according to the pressure value detected by the first sensor 31, so that the pressure value in the accommodating box 30 is consistent with the external pressure value.

It is to be noted that, during the waiting time of the unified pod between two processes, the first sensor 31 can continuously detect the pressure value in the accommodating box 30, and the opening and closing of the gas inlets and gas outlets 35 of the accommodating box 30 is adjusted according to the detected pressure value.

Continuously referring to FIG. 1, the gas storage box 50 may be filled with the highly compressed protective gas. For example, the protective gas is compressed by a compression pump and other devices and then filled into the gas storage box 50. As shown in FIG. 2, a second sensor 51 may be further arranged in the gas storage box 50. The second sensor 51 may be arranged on the top of the gas storage box 50 to detect the concentration value or pressure value of the protective gas in the gas storage box 50. The second sensor 51 may be in signal connection to the processor of the unified pod.

In some possible examples, the second sensor 51 detects the concentration value of the protective gas in the gas storage box 50 and can transmit the detected concentration information of the protective gas to the processor of the unified pod in a wired or wireless manner. When the concentration value of the protective gas detected by the second sensor 51 is less than a second set value, the controller gives an alarm to prompt the user to replace the gas storage box 50.

In some possible examples, the second sensor 51 detects the pressure value in the gas storage box 50 and transmits the detected pressure information to the processor of the unified pod in a wired or wireless manner. When the pressure value detected by the second sensor 51 is less than a third set value, the controller gives an alarm to prompt the user to replace the gas storage box 50.

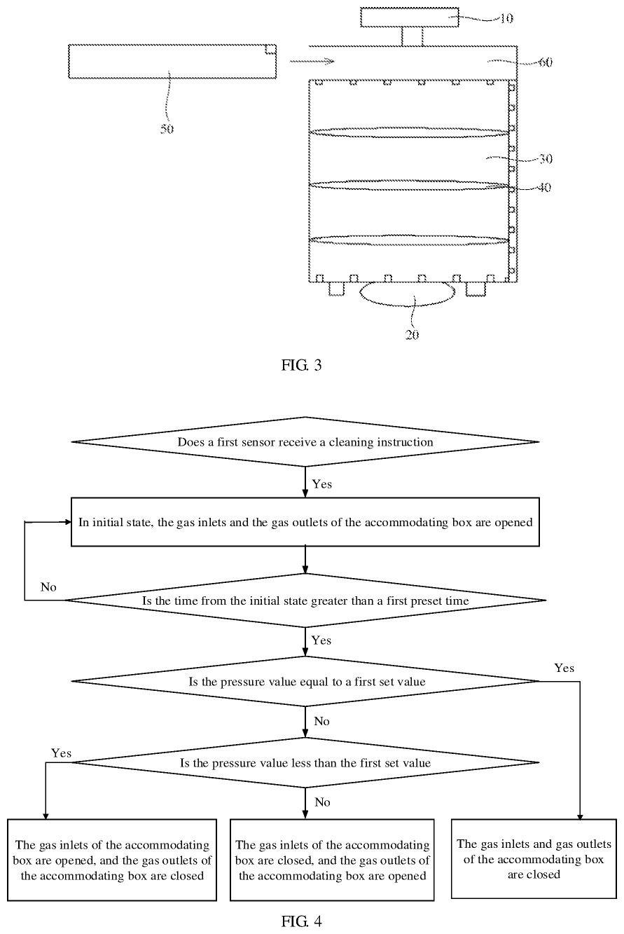

The gas storage box 50 is detachably connected to the accommodating box 30. For example, a clamping slot 60 is formed on the accommodating box 30, and the gas storage box 50 is clamped into the clamping slot 60. The gas storage box 50 may be manufactured according to a unified specification. With such an arrangement, it is convenient to replace the gas storage box 50, and the time required to replace the gas storage box 50 is reduced. As shown in FIG. 3, when it is necessary to replace the gas storage box 50, the used gas storage box 50 is pulled out of the clamping slot 60, and a new gas storage box 50 is inserted into the clamping slot 60.

Alternatively, the gas inlet of the gas storage box 50 is connected to a protective gas pump. When it is necessary to replace the gas storage box 50, the protective gas is filled into the gas storage box 50 by the protective gas pump to maintain the content of the protective gas in the gas storage box 50. With such an arrangement, when the protective gas in the gas storage box 50 is insufficient, the protective gas can be filled in time, avoiding that the protective gas in the accommodating box 30 cannot cover the wafer 40.

In the embodiments of the present application, the unified pod comprises an accommodating box 30 and a gas storage box 50, wherein an object to be conveyed is placed in the accommodating box 30, and a protective gas is filled in the gas storage box 50; gas inlets and gas outlets 35 are formed on the accommodating box 30; the gas inlets of the accommodating box 30 are connected with the gas storage box 50; a first sensor 31 for detecting a pressure value in the accommodating box 30 is further arranged in the accommodating box 30; in initial state, the gas storage box fills the accommodating box 30 with the protective gas by the gas inlets of the accommodating box 30, and the gas outlets 35 of the accommodating box 30 are opened; and, when the time from the initial state is greater than a first set time and the pressure value is less than a first set value, the gas outlets 35 of the accommodating box 30 are closed, and the accommodating box 30 fills the accommodating box 30 with the protective gas by the gas inlets of the accommodating box 30. By continuously filling the protective gas into the accommodating box 30, the accommodating box 30 is continuously filled with the protective gas after the waste gas in the accommodating box 30 is discharged, so that the object to be conveyed in the accommodating box 30 is in the protective gas, the object to be conveyed in the accommodating box 30 is prevented from being polluted, the surface defects of the object to be conveyed are reduced, and the yield of the object to be conveyed is improved.

Various embodiments or implementations in this specification have been described progressively, and each embodiment focuses on the differences from other embodiments, so the same and similar parts of the embodiments may refer to each other.

It should be understood that, in the disclosure of the present application, the orientations or positional relationships indicated by terms “longitudinal”, “transverse”, “upper”, “lower”, “front”, “rear”, “left”, “right”, “vertical”, “horizontal”, “top”, “bottom”, “inside”, “outside”, etc. are orientations and the positional relationships shown based on the drawings, merely for describing the present application and simplifying the description, rather than indicating or implying that the stated systems or elements must have a particular orientation or be constructed and operated in a particular orientation. Therefore, the terms shall not be interpreted as any limitations to the present application.

In the description of this specification, the description with reference to terms “an implementation”, “some implementations”, “a schematic implementation”, “an example”, “a specific example” or “some examples” means that specific features, structures, materials or characteristics described with reference to the implementation or example are included in at least one implementation or example of the present application. In this specification, the schematic expressions of the terms do not necessarily refer to the same embodiment or example. In addition, the described specific features, structures, materials or characteristics may be combined in any one or more implementations or examples in a proper way.

Finally, it is to be noted that the foregoing embodiments are only used for describing the technical solutions of the present application, rather than limiting the present application. Although the present application has been described in detail by the foregoing embodiments, a person of ordinary skill in the art should understood that modifications can still be made to the technical solutions recorded in the foregoing embodiments or equipment replacements can be made to some or all of the technical features, and these modifications or replacements do not make the essence of the corresponding technical solutions depart from the scope of the technical solutions in the embodiments of the present application.

1. An unified pod, comprising an accommodating box and a gas storage box, wherein gas inlets and gas outlets are formed on the accommodating box; the gas inlets of the accommodating box are connected with the gas storage box; a first sensor is further arranged in the accommodating box; and the first sensor detects a pressure value in the accommodating box;
in initial state, the gas outlets of the accommodating box are opened, and the gas storage box fills the accommodating box with a protective gas by the gas inlets of the accommodating box; and, when the time from the initial state is greater than a first set time and the pressure value is less than a first set value, the gas outlets of the accommodating box are closed, and the gas storage box fills the accommodating box with the protective gas by the gas inlets of the accommodating box.

2. The unified pod according to claim 1, wherein, when the time from the initial state is greater than the first set time and the pressure value is greater than the first set value, the gas inlets of the accommodating box are closed, and the gas outlets of the accommodating box are opened.

3. The unified pod according to claim 1, wherein, when the time from the initial state is greater than the first set time and the pressure value is equal to the first set value, the gas inlets and gas outlets of the accommodating box are closed.

4. The unified pod according to claim 1, wherein, when the time from the initial state is less than the first set time, the gas inlets and gas outlets of the accommodating box are opened, and the gas storage box fills the accommodating box with the protective gas by the gas inlets of the accommodating box, so that a waste gas in the accommodating box is discharged through the gas outlets of the accommodating box.

5. The unified pod according to claim 1, wherein the accommodating box is a cylindrical box, and the gas inlets of the accommodating box comprise a plurality of first gas inlets arranged on sidewall of the accommodating box, and the plurality of first gas inlets are arranged at intervals along an axial direction of the accommodating box.

6. The unified pod according to claim 5, wherein the gas inlets of the accommodating box further comprise a plurality of second gas inlets arranged on top of the accommodating box and a plurality of third gas inlets arranged on bottom of the accommodating box.

7. The unified pod according to claim 6, wherein, when the pressure value is less than the first set value, the gas storage box fills the accommodating box with the protective gas at a first flow rate by the first gas inlets, the second gas inlets and the third gas inlets.

8. The unified pod according to claim 6, wherein the third gas inlets are arranged on the same side of the accommodating box as the gas outlets of the accommodating box; and
when the time from the initial state is less than the first set time, the gas storage box fills the accommodating box with the protective gas at a second flow rate by the first gas inlets and the second gas inlets, and the third gas inlets are closed.

9. The unified pod according to claim 1, wherein a second sensor is arranged in the gas storage box; the second sensor detects a concentration value of the protective gas in the gas storage box; and, when the concentration value of the protective gas is less than a second set value, the protective gas in the gas storage box is insufficient.

10. A material conveying system, comprising a conveyor chain, a driving device and the unified pod according to claim 1;
wherein, the unified pod is suspended on the conveyor chain, and the driving device drives the conveyor chain to move.
